(19) United States
(12) Patent Application Publication
(10) Pub. No.: US 2011/0247559 A1
(43) Pub. Date: Oct. 13, 2011

(54) GAS DISTRIBUTION SHOWER MODULE AND FILM DEPOSITION APPARATUS

(75) Inventors: Jun-Chin Liu, Hsinchu City (TW); Yen-Yu Pan, Hsinchu City (TW); Chih-Yung Huang, Taichung County (TW); Jung-Chen Chien, Hsinchu County (TW); Shun-Yuan Lo, Miaoli County (TW)

(73) Assignee: INDUSTRIAL TECHNOLOGY RESEARCH INSTITUTE, Hsinchu (TW)

(21) Appl. No.: 12/853,315

(22) Filed: Aug. 10, 2010

(30) Foreign Application Priority Data
Apr. 13, 2010 (TW) 99111452

(51) Int. Cl. C23C 16/505; C23C 16/00; F16L 41/00

(52) U.S. Cl. 118/723 R; 137/561 A

(57) ABSTRACT

A gas distribution shower module and a film deposition apparatus are provided. The gas distribution shower module includes a first distributor, a second distributor, a third distributor and a fourth distributor. The second distributor is under the first distributor, the third distributor is under the second distributor, the fourth distributor is under the third distributor, and a distance is between the fourth distributor and the third distributor. The third distributor is divided into an inner region and an outer region, and an area ratio of the inner region to the outer region is from 1:1 to 1:5. Furthermore, the third distributor has a plurality of gas holes in the inner region and the outer region, and an area ratio of the gas holes in the inner region to the gas holes in the outer region is from 1:1 to 1:5.

### CROSS-REFERENCE TO RELATED APPLICATION

This application claims the priority benefit of Taiwan application serial no. 99111452, filed on Apr. 13, 2010. The entirety of the above-mentioned patent application is hereby incorporated by reference herein and made a part of this specification.

### TECHNICAL FIELD

The disclosure is related to a gas distribution shower module and a film deposition apparatus.

### BACKGROUND

With the development of film deposition processes, how to make the gas uniformly spraying in a chamber during a chemical vapor deposition (CVD) process is important. Currently, a shower head is often used to improve the gas spray uniformity in a CVD apparatus. A general shower head is shown in FIG. 1. A metal disc shower head 102 in the CVD chamber 100 has many symmetrical gas holes 104 in order to let the gas via the shower head 102 from a gas inlet be uniformly sprayed to the substrate 110 on the substrate base 108.

However, the deeper the gas holes 104 in the shower head 102 is drilled, the more the material cost and the manufacturing cost are spent. In order to avoid the cost increasing, a buffer region 200 is added, such that the gas may be stabilized after passing through the buffer region 200 from the gas inlet 106, and then the gas may be uniformly sprayed out through the shower head 102, as shown in FIG. 2.

The CVD film deposition apparatus of FIG. 1 and FIG. 2 are utilized to performed the film deposition process with a low gas flow rate. Thus, it is not satisfied to use only one buffer region 200 and only one shower head 120 if the film deposition process is performed with a high gas flow rate. The reason is the area of the gas inlet is constant, and the gas velocity is increased as the gas flow rate increased. Therefore, the gas velocity is higher at the central portion of the shower head 102 than at the edge portion of the shower head 102, as shown in FIG. 2. As a result, the gas is accumulated at the central portion of the substrate 110 in the CVD film deposition apparatus of FIG. 2, and thereby the thickness of the film deposited on the substrate 110 is not uniform.

In order to prevent the gas having non-uniform flow rate, a gas distributor is provided in U.S. Pat. No. 7,270,713. Referring to FIG. 3, the gas distributor 300 includes a distributor 302, a regulating plate 304 and a lining plate 306. The distributor 302, the regulating plate 304 and the lining plate 306 have gas channels 308 therein. In the US patent, each gas channel 308 is constituted by a large gas hole 310, a small gas hole 312, a bell-shaped end 314, another large gas hole 316 and another bell-shaped end 318. The small gas hole 312 is connected with the large gas holes 310 and 316 so as to make the gas sufficiently passing through the distributor 302 and provide an enough flow-resistance to slow down the gas flow, and thereby the gas may be uniformly sprayed into the chamber. However, this gas distributor has disadvantages of high cost and being difficult to manufacture.

### SUMMARY

A gas distribution shower module is provide that includes a first distributor, a second distributor, a third distributor and a fourth distributor. The second distributor is under the first distributor, the third distributor is under the second distributor, the fourth distributor is under the third distributor, and a distance is between the fourth distributor and the third distributor. The third distributor is divided into an inner region and an outer region, and an area ratio of the inner region to the outer region is from 1:1 to 1:5. The third distributor has a plurality of gas holes in the inner region and the outer region, and an area ratio of the gas holes in the inner region to the gas holes in the outer region is from 1:1 to 1:5.

A film deposition apparatus is provided that includes a chamber, a gas distribution shower module in the chamber, a substrate base in the chamber and corresponding to the gas distribution shower module, and a radio frequency power source for generating plasma. The gas distribution shower module includes a first distributor, a second distributor, a third distributor and a fourth distributor.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic cross-sectional view of a conventional CVD film deposition apparatus.

FIG. 2 is a schematic cross-sectional view of another conventional CVD film deposition apparatus.

FIG. 3 is a perspective schematic view of a gas distributor disclosed in U.S. Pat. No. 7,270,713.

FIG. 4 is a schematic cross-sectional view of a gas distribution shower module according to a first embodiment of the present invention.

FIG. 5 is a cross-sectional view showing the third and fourth distributors of FIG. 4.

FIG. 6 is a top view showing the third distributor of FIG. 4

FIG. 7 is a schematic cross-sectional view of a film deposition apparatus according to a second embodiment of the present invention.

FIG. 8 shows the relation between the electrode spacing and the crystalline ratio of the deposited film of Example 2.

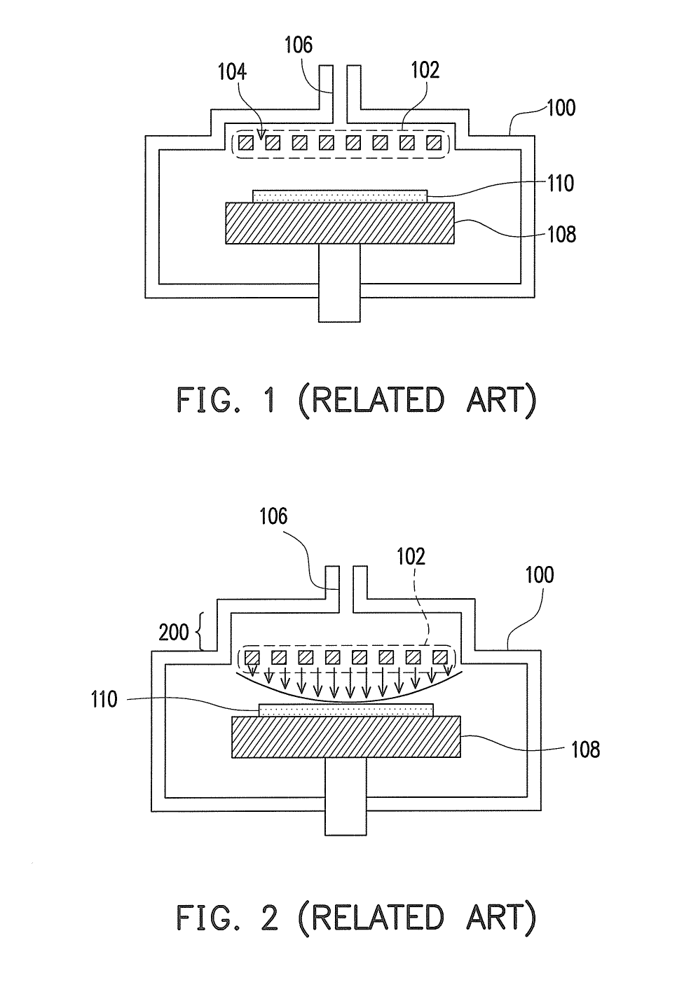

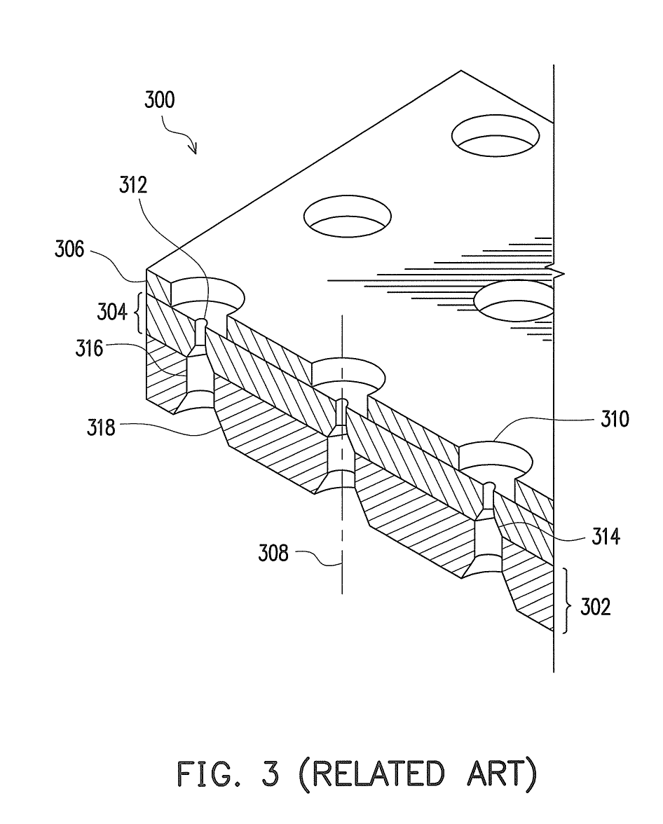

### DETAILED DESCRIPTION OF DISCLOSED EMBODIMENTS

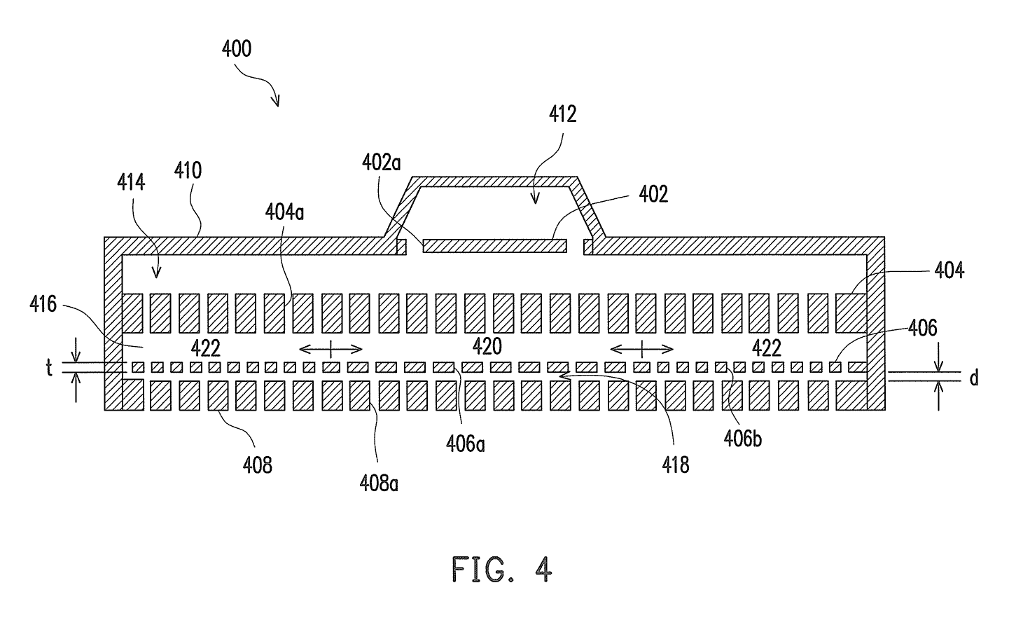

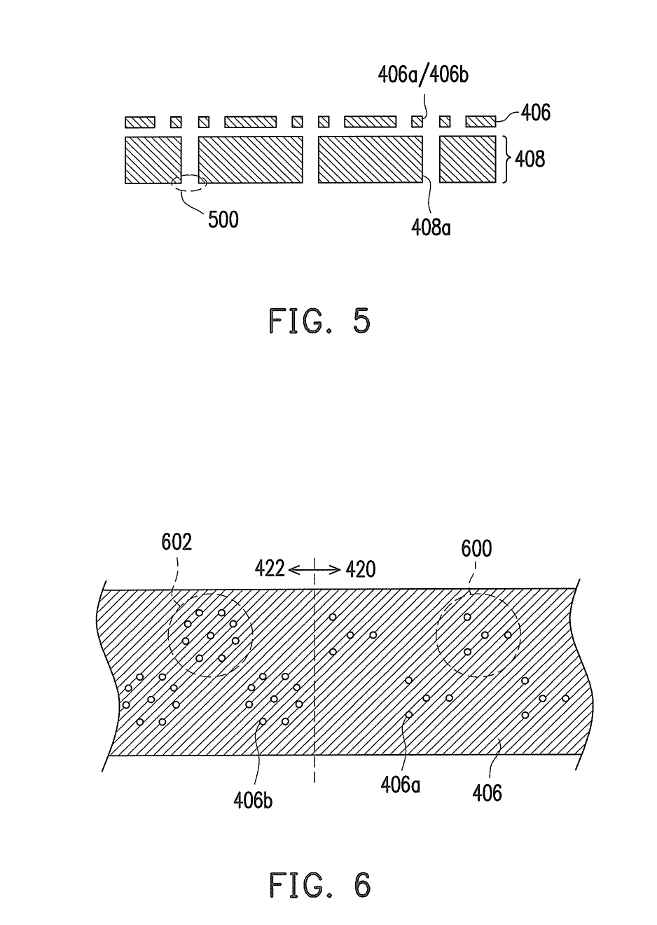

FIG. 4 is a schematic cross-sectional view of a gas distribution shower module according to a first embodiment of the present invention.

Referring to FIG. 4, the gas distribution shower module 400 of the embodiment comprises a first distributor 402, a second distributor 404, a third distributor 406 and a fourth distributor 408. Even though a gas inlet is not shown in the drawing, the gas is injected from the top portion toward the lower portion, which is well known to people having ordinary skill in the art. Therefore, the first, second, third and fourth distributors 402-408 are arranged from top to bottom, and each of the distributors 402-408 has gas holes which make the gas passing through. The profile of the gas distribution shower module 400 may be designed based on the shape of the substrate disposed underneath. For instance, if the substrate to be deposited is a semiconductor wafer, the gas distribution shower module 400 may be circular-shaped; if the substrate to be deposited is a flat display panel, the gas distribution shower module 400 may be polygonal-shaped, such as rectangle. Generally, the first, second, third and fourth distributors 402-408 are metal distributors, which are made by aluminum or stainless steel, so as to connect with a radio frequency (RF) power source. Moreover, the gas distribution shower module 400 further comprises a supporting structure 410 to support the first, second, third and fourth distributors 402-408.

As shown in FIG. 4, in the embodiment, the gas is injected from the top portion toward the lower portion, and thus the gas may pass through the space above the first distributor 402 which serves as a buffer region. If the gas injected into the gas distribution shower module 400 is a mixed gas, the space 412 serves as a mixing region. After that, the gas may reach the space 414 between the first distributor 402 and the second distributor 404 through the gas holes 402a of the first distributor 402, and then diffuse toward the edge of the second distributor 404. Next, the gas may pass through the gas holes 404a of the second distributor 404 and reach the space 416 between the second distributor 404 and the third distributor 406. Then, the gas may pass through the gas holes 406a, 406b of the third distributor 406 and reach the space 418 between the third distributor 406 and the fourth distributor 408. In particular, the third distributor 406 is divided into an inner region 420 and an outer region 422, and an area ratio of the inner region 420 to the outer region 422 is from 1:1 to 1:5. An area ratio of the gas holes 406a in the inner region 420 to the gas holes 406b in the outer region 422 is from 1:1 to 1:5. The problem of non-uniform gas flow rate is resolved by using the above mentioned design, and it is more suitable for applying to the film deposition with large area. The distance “d” between the third distributor 406 and the fourth distributor 408 is 0.1 cm-3 cm, for example, which is adapted to a film deposition with a high pressure of 3 Torr-10 Torr. Thereafter, the gas may uniformly diffuse and pass through the gas holes 408a of the fourth distributor 408.

In the embodiment, the thickness t of the third distributor 406 is 0.1 cm-0.2 cm, for example, such that a fast and accurate laser cutting process can be introduced. Comparing with drilling the plate having a thickness of 2 cm-5 cm in the prior art, the manufacturing time and the manufacturing cost of the embodiment can be reduced. The gas holes 402a, 404a, 406a, 406b and 408a may be circular holes or other-shaped holes with an identical diameter. In addition, in the embodiment, the gas holes 408a of the fourth distributor 408 may not align to the gas holes 406a/406b of the third distributor 406; or each of the gas holes 408a may align to a portion of the gas holes 406a/406b of the third distributor 406. Generally, the gas holes 408a of the fourth distributor 408 respectively align to the gas holes 406a/406b of the third distributor 406. When the film deposition process is performed with a high pressure of 3 Torr-10 Torr, the gas holes 408a of the fourth distributor 408 and the gas holes 406a/406b of the third distributor 406 are alternatively arranged, so as to reduce the plasma generated by arc at the outlet 500 of the gas holes 408a If the plasma is generated at the outlet 500, the deposited film may be contaminated owing to a deposition at the outlet 500 or a damage of the fourth distributor 408 (that is electrode ionization) happens.

Furthermore, in the embodiment, since the area ratio of the gas holes 406a in the inner region 420 of the third distributor 406 to the gas holes 406b in the outer region 422 of the third distributor 406 is 1:1-1:5, the gas holes 406a and the gas holes 406b may be arranged to be different patterns. The gas holes 406a in the inner region 420 of the third distributor 406 are arranged as a plurality of first patterns 600, and the gas holes 406b in the outer region 422 of the third distributor 406 are arranged as a plurality of second patterns 602. The first patterns 600 are different from the second patterns 602. Certainly, the gas holes 406a and the gas holes 406b of the third distributor 406 may also be arranged as other patterns, and are not limited to the embodiment of FIG. 6. According to the embodiment, a gas flow field simulation method (CFD) is used to obtain the distributions of the gas velocity and the gas pressure in the chamber, and the gas distribution shower module 400 may be adjusted based on these two factors.

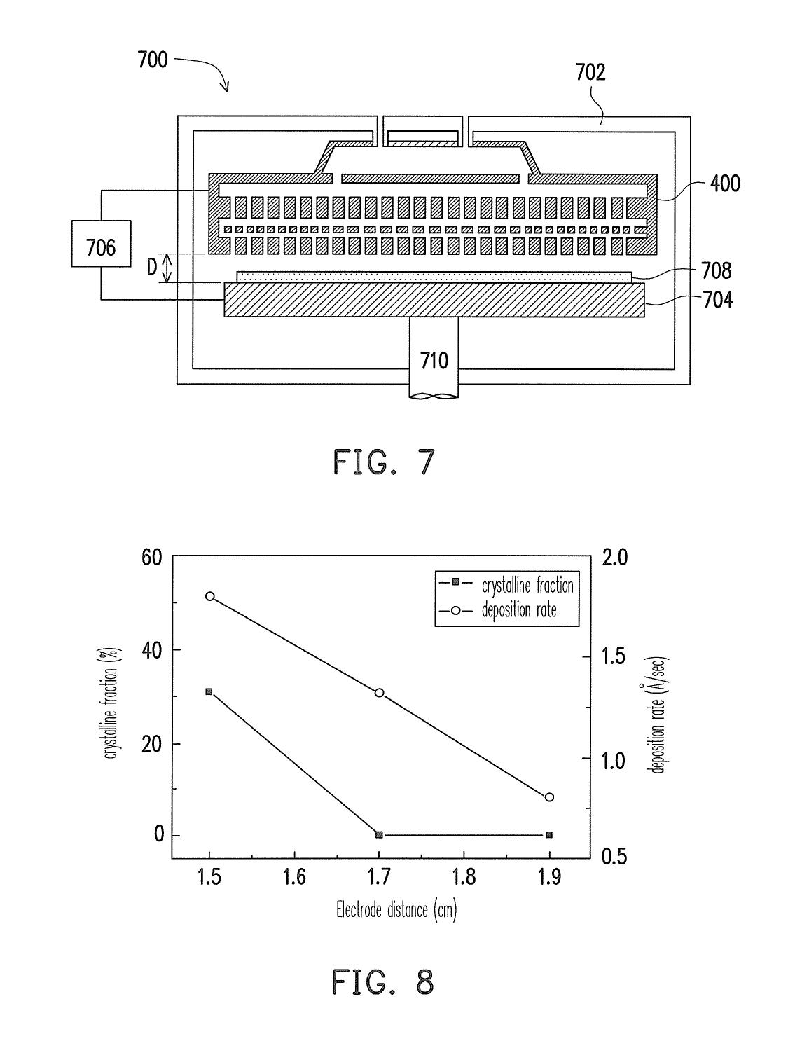

FIG. 7 is a schematic cross-sectional view of a film deposition apparatus according to a second embodiment of the present invention. Elements of the present (second) embodiment identical to those in the first embodiment are represented with similar or the same reference numerals.

Referring to FIG. 7, the film deposition apparatus 700 of the embodiment comprises a chamber 702, a gas distribution shower module 400 in the chamber 702, a substrate base 704 in the chamber 702 and corresponding to the gas distribution shower module 400, and a radio frequency power source 706 for generating plasma in the chamber 702. The gas distribution shower module 400 is described in the first embodiment, and the substrate base 704 is used for placing a substrate 708. The distance D between the gas distribution shower module 400 and the substrate base 704 is reduced because the gas can be uniformly sprayed by using the gas distribution shower module 400. The distance D between the gas distribution shower module 400 and the substrate base 704 can be reduced to 0.5 cm-2 cm, so as to increase the deposition rate. In the embodiment, the substrate base 704 comprises a heat plate, such that the substrate 708 disposed thereon can be heated to a predetermined temperature. In addition, the substrate base 704 may also be connected to a hoist system 710 so as to adjust the substrate base 704 to a higher position for deposition (as shown in FIG. 7) and adjust the substrate base 704 to a lower position for easily moving the substrate 708 in and out the chamber 702.

The following examples are described for illustration.

### Example 1

The film deposition apparatus as shown in FIG. 7 is provided. In the gas distribution shower module of the film deposition apparatus, the area ratio of the inner region of the third distributor to the outer region of the third distributor is 1:5, the area ratio of the gas holes in the inner region to the gas holes in the outer region is 1:5, the distance between the third distributor and the fourth distributor is 1.5 cm, and the distance between the gas distribution shower module and the substrate base is 1.9 cm.

Then, a micro-crystalline silicon film deposition process is performed on a silicon wafer. In the film deposition process, a high radio frequency and a mixed gas composed of SiH₄ and H₂ are used, wherein SiH₄/H₂=200 sccm/2000 sccm (11.76%). The process pressure P=5 Torr, and the power=900 W.

After the film deposition process is finished, the silicon wafer is moved out, and the thicknesses of the micro-crystalline silicon film on different positions of the silicon wafer are measured and listed in Table 1.

TABLE 1

| Measuring position | X axis | Y axis | Thickness (Å) |
|---|---|---|---|
| 1 | 121.91 | 95.78 | 1043 |
| 2 | 121.91 | 454.22 | 1064.5 |
| 3 | 235.95 | 185.38 | 1181 |
| 4 | 235.95 | 364.62 | 1047.8 |
| 5 | 350 | 275 | 1383.4 |
| 6 | 464.04 | 185.4 | 1084.1 |
| 7 | 464.04 | 364.6 | 1106.4 |
| 8 | 578.08 | 95.8 | 1214.5 |
| 9 | 578.08 | 454.2 | 1029 |

The uniformity of the micro-crystalline silicon film is 14.7% which is calculated from Table 1.

### Example 2

The film deposition apparatus and the process conditions in Example 2 are the similar to that in Example 1, but the distance between the gas distribution shower module and the substrate base (electrode spacing) is changed to 1.5 cm, 1.7 cm and 1.9 cm.

After finishing the process, the silicon wafer is moved out. The crystalline fraction of the micro-crystalline silicon film is measured and the deposition rate is calculated. As shown in FIG. 8, if the distance between the gas distribution shower module and the substrate base is reduced, the crystalline fraction of the deposited film is increased and the deposition rate is also increased. In a conventional high pressure film deposition apparatus, the distance between the gas distribution module and the substrate base can not be reduced, and therefore the deposited film is easily contaminated owing to the plasma generation at the distributor outlet and the damage of the distributor (that is electrode ionization). On the contrary, the contamination problem does not happen in the film deposition apparatus in Example 1 and Example 2, and the crystalline fraction and the deposition rate of the deposited film are increased through reducing the distance between the gas distribution shower module and the substrate base.

To sum up, because the gas distribution shower module is formed by a plurality of thin plates, and thereby, it is easy to assembled, the manufacturing cost of the gas holes of the distributor is low, and the maintenance is simple. The distribution of the gas holes in the distributor is based on the area ratio of the gas holes in the inner region to the gas holes in the outer region. Because the gases enter the chamber through a plurality of distributors, the gases can be uniformly mixed before entering the chamber. Therefore, the deposited film has a uniform thickness, and the plasma is not generated at the outlet of the fourth distributor of the gas distribution shower module during the film deposition process with high pressure and reduced deposition distance.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A gas distribution shower module, comprising:
a first distributor;
a second distributor, disposed under the first distributor;
a third distributor, disposed under the second distributor; and
a fourth distributor, disposed under the third distributor, wherein a distance is between the fourth distributor and the third distributor,
the third distributor is divided into an inner region and an outer region, and an area ratio of the inner region to the outer region is from 1:1 to 1:5, and
the third distributor has a plurality of gas holes in the inner region and the outer region, and an area ratio of the gas holes in the inner region to the gas holes in the outer region is from 1:1 to 1:5.

2. The gas distribution shower module of claim 1, wherein a thickness of the third distributor is 0.1-0.2 cm.

3. The gas distribution shower module of claim 1, wherein the distance between the fourth distributor and the third distributor is 0.1-3 cm.

4. The gas distribution shower module of claim 1, wherein the fourth distributor has a plurality of gas holes, and the gas holes of the fourth distributor do not align to the gas holes of the third distributor.

5. The gas distribution shower module of claim 1, wherein the fourth distributor has a plurality of gas holes, and each of the gas holes of the fourth distributor aligns to a portion of the gas holes of the third distributor.

6. The gas distribution shower module of claim 1, wherein the gas holes in the inner region of the third distributor are arranged as a plurality of first pattern, and the gas holes in the outer region of the third distributor are arranged as a plurality of second patterns.

7. The gas distribution shower module of claim 6, wherein the first patterns are different from the second patterns.

8. The gas distribution shower module of claim 1, wherein the first, second, third and fourth distributors are metal distributors.

9. The gas distribution shower module of claim 1, further comprising a supporting structure to support the first, second, third and fourth distributors in a chamber.

10. A film deposition apparatus, comprising:
a chamber;
a gas distribution shower module, disposed in the chamber;
a substrate base, disposed in the chamber and disposed corresponding to the gas distribution shower module;
a radio frequency power source, for generating plasma in the chamber, wherein the gas distribution shower module comprises:
a first distributor;
a second distributor, disposed under the first distributor;
a third distributor, disposed under the second distributor;
a fourth distributor, disposed under the third distributor, wherein a distance is between the fourth distributor and the third distributor,
the third distributor is divided into an inner region and an outer region, and an area ratio of the inner region to the outer region is from 1:1 to 1:5, and
the third distributor has a plurality of gas holes in the inner region and the outer region, and an area ratio of the gas holes in the inner region to the gas holes in the outer region is from 1:1 to 1:5.

11. The film deposition apparatus of claim 10, wherein a thickness of the third distributor is 0.1-0.2 cm.

12. The film deposition apparatus of claim 10, wherein the distance between the fourth distributor and the third distributor is 0.1 cm-3 cm.

13. The film deposition apparatus of claim 10, wherein the fourth distributor has a plurality of gas holes, and the gas holes of the fourth distributor do not align to the gas holes of the third distributor.

14. The film deposition apparatus of claim 10, wherein the fourth distributor has a plurality of gas holes, and each of the gas holes of the fourth distributor aligns to a portion of the gas holes of the third distributor.

15. The film deposition apparatus of claim 10, wherein the gas holes in the inner region of the third distributor are arranged as a plurality of first pattern, and the gas holes in the outer region of the third distributor are arranged as a plurality of second patterns.

16. The film deposition apparatus of claim 15, wherein the first patterns are different from the second patterns.

17. The film deposition apparatus of claim 10, wherein the first, second, third and fourth distributors are metal distributors.

18. The film deposition apparatus of claim 10, wherein the gas distribution shower module further comprises a supporting structure to support the first, second, third and fourth distributors.

19. The film deposition apparatus of claim 10, wherein the substrate base comprises a heat plate.
